(19) United States
(12) Patent Application Publication
(10) Pub. No.: US 2025/0183849 A1
(43) Pub. Date: Jun. 5, 2025

(54) DOHERTY AMPLIFIER CIRCUIT AND SEMICONDUCTOR DEVICE

(71) Applicant: SUMITOMO ELECTRONIC DEVICE INNOVATIONS, INC., Yokohama-shi (JP)

(72) Inventor: Takashi SUMIYOSHI, Yokohama-shi (JP)

(73) Assignee: SUMITOMO ELECTRONIC DEVICE INNOVATIONS, INC., Yokohama-shi (JP)

(21) Appl. No.: 18/939,482

(22) Filed: Nov. 6, 2024

(30) Foreign Application Priority Data
Nov. 30, 2023 (JP) 2023-203090

(51) Int. Cl. H03F 1/02; H01L 23/66; H03F 1/56

(52) U.S. Cl. CPC H03F 1/0288; H01L 23/66; H03F 1/56; H01L 2223/6611; H01L 2223/6655

(57) ABSTRACT

A Doherty amplifier circuit includes a divider dividing a received input signal into a first signal, a second signal, and a third signal, a main amplifier amplifying the first signal and output the amplified first signal as a fourth signal, a first peak amplifier amplifying the second signal and output the amplified second signal as a fifth signal, a second peak amplifier amplifying the third signal and output the amplified third signal as a sixth signal, a combiner combining the fourth signal, the fifth signal, and the sixth signal into a combined signal and output the combined signal to an output terminal as an output signal, and a semiconductor chip including the main amplifier, the first peak amplifier, and the second peak amplifier.

### CROSS REFERENCE TO RELATED APPLICATIONS

This application claims priority based on Japanese Patent Application No. 2023-203090 filed on Nov. 30, 2023, and the entire contents of the Japanese patent application are incorporated herein by reference.

### TECHNICAL FIELD

The present invention relates to a Doherty amplifier circuit and a semiconductor device.

### BACKGROUND ART

It is known an N-way (N is three or more) Doherty amplifier circuit using a main amplifier and two or more peak amplifiers (for example, U.S. Pat. Nos. 8,022,760 and 10,601,375). It is known that a main amplifier and a peak amplifier are provided on an identical semiconductor chip (for example, WO 2023/187921).

### SUMMARY OF THE INVENTION

A Doherty amplifier circuit according to an embodiment of the present disclosure includes a divider that divides a received input signal into a first signal, a second signal, and a third signal, a main amplifier that amplifies the first signal and outputs an amplified first signal as a fourth signal, a first peak amplifier that amplifies the second signal and outputs an amplified second signal as a fifth signal, a second peak amplifier that amplifies the third signal and outputs an amplified third signal as a sixth signal, a combiner that combines the fourth signal, the fifth signal, and the sixth signal into a combined signal and output the combined signal to an output terminal as an output signal, and a semiconductor chip including the main amplifier, the first peak amplifier, and the second peak amplifier. An input power of the input signal at which the second peak amplifier is turned on is larger than an input power of the input signal at which the first peak amplifier is turned on, and the main amplifier and the first peak amplifier are adjacent to each other.

A Doherty amplifier circuit according to an embodiment of the present disclosure includes a divider that divides a received input signal into a first signal, a second signal, and a third signal, a main amplifier that amplifies the first signal and outputs an amplified first signal as a fourth signal, a first peak amplifier that amplifies the second signal and outputs an amplified second signal as a fifth signal, a second peak amplifier that amplifies the third signal and outputs an amplified third signal as a sixth signal, a combiner that combines the fourth signal, the fifth signal, and the sixth signal into a combined signal and outputs the combined signal to an output terminal as an output signal, a first semiconductor chip including the main amplifier and the first peak amplifier, and a second semiconductor chip different from the first semiconductor chip and including the second peak amplifier. An input power of the input signal at which the second peak amplifier is turned on is larger than an input power of the input signal at which the first peak amplifier is turned on.

A semiconductor device for a Doherty amplifier circuit according to an embodiment of the present disclosure includes a main amplifier that amplifies a first signal divided from an input signal and outputs an amplified first signal as a fourth signal, a first peak amplifier that amplifies a second signal divided from the input signal and outputs an amplified second signal as a fifth signal, a second peak amplifier that amplifies a third signal divided from the input signal and outputs an amplified third signal as a sixth signal, and a semiconductor chip including the main amplifier, the first peak amplifier, and the second peak amplifier. An input power of the input signal at which the second peak amplifier is turned on is larger than an input power of the input signal at which the first peak amplifier is turned on, and the main amplifier and the first peak amplifier are adjacent to each other.

A semiconductor device for a Doherty amplifier circuit according to an embodiment of the present disclosure includes a main amplifier that amplifies a first signal divided from an input signal and outputs an amplified first signal as a fourth signal, a first peak amplifier that amplifies a second signal divided from the input signal and outputs an amplified second signal as a fifth signal, a second peak amplifier that amplifies a third signal divided from the input signal and outputs an amplified third signal as a sixth signal, a first semiconductor chip including the main amplifier and the first peak amplifier, and a second semiconductor chip different from the first semiconductor chip and including the second peak amplifier. An input power of the input signal at which the second peak amplifier is turned on is larger than an input power of the input signal at which the first peak amplifier is turned on.

### BRIEF DESCRIPTION OF THE DRAWINGS

FIG. 1 is a block diagram of a Doherty amplifier circuit according to a first embodiment.

FIG. 2 is a plan view of a semiconductor device in the first embodiment.

FIG. 3 is a cross-sectional view of a semiconductor chip in the first embodiment.

FIG. 4 is a schematic diagram illustrating the probability for Pout, Pout of each amplifier for Pin, the gain of each amplifier for Pin, and the overall gain for Pin in the first embodiment.

FIG. 5 is a plan view of a semiconductor device in a comparative example.

FIG. 6 is a plan view of a semiconductor device in a second embodiment.

### DETAILED DESCRIPTION

When the difference in characteristics such as parasitic capacitance between a main amplifier and a plurality of peak amplifiers is large, the phases between amplifiers shift from a desired difference, and the characteristics such as gain deteriorate. In an N-way (Nis three or more) Doherty amplifier circuit, it is not known how to arrange the main amplifier and the plurality of peak amplifiers to improve the characteristics.

An object of the present disclosure is to suppress deterioration of the characteristics.

### Description of Embodiments of Present Disclosure

First, the contents of embodiments of the present disclosure will be listed and explained.
(1) A Doherty amplifier circuit according to an embodiment of the present disclosure includes a divider that divides a received input signal into a first signal, a second signal, and a third signal, a main amplifier that amplifies the first signal and outputs an amplified first signal as a fourth signal, a first peak amplifier that amplifies the second signal and outputs an amplified second signal as a fifth signal, a second peak amplifier that amplifies the third signal and output an amplified third signal as a sixth signal, a combiner that combines the fourth signal, the fifth signal, and the sixth signal into a combined signal and outputs the combined signal to an output terminal as an output signal, and a semiconductor chip including the main amplifier, the first peak amplifier, and the second peak amplifier. An input power of the input signal at which the second peak amplifier is turned on is larger than an input power of the input signal at which the first peak amplifier is turned on, and the main amplifier and the first peak amplifier are adjacent to each other. Thus, the difference in parasitic capacitance or the like between the main amplifier and the first peak amplifier can be reduced. Since the phases of the fourth signal and the fifth signal can be matched, the deterioration of the characteristics can be suppressed.
(2) In (1), the first peak amplifier may be disposed between the main amplifier and the second peak amplifier. Thus, the deterioration of the characteristics can be further suppressed.
(3) In (1) or (2), the main amplifier and the first peak amplifier may be adjacent to each other in a first direction, and a distance between the main amplifier and the first peak amplifier may be smaller than a width of the main amplifier in the first direction and smaller than a width of the first peak amplifier in the first direction. Thus, the deterioration of the characteristics can be further suppressed.
(4) In any one of (1) to (3), the Doherty amplifier circuit may further include a first input pad disposed on the semiconductor chip and electrically connected to an input terminal of the main amplifier, a second input pad disposed on the semiconductor chip and electrically connected to an input terminal of the first peak amplifier, a third input pad disposed on the semiconductor chip and electrically connected to an input terminal of the second peak amplifier, a first output pad disposed on the semiconductor chip and electrically connected to an output terminal of the main amplifier, a second output pad disposed on the semiconductor chip and electrically connected to an output terminal of the first peak amplifier, and a third output pad disposed on the semiconductor chip and electrically connected to an output terminal of the second peak amplifier. Thus, the main amplifier, the first peak amplifier, and the second peak amplifier can be electrically connected to the outside.
(5) In (4), the main amplifier, the first peak amplifier, and the second peak amplifier may be arranged in a first direction, the first input pad and the first output pad may be located with the main amplifier interposed therebetween in a second direction intersecting the first direction, the second input pad and the second output pad may be located with the first peak amplifier interposed therebetween in the second direction, and the third input pad and the third output pad may be located with the second peak amplifier interposed therebetween in the second direction. Thus, the main amplifier and the first peak amplifier can be adjacent to each other.
(6) In any one of (1) to (5), the semiconductor chip may include no passive element. Thus, the main amplifier and the first peak amplifier can be adjacent to each other, and the first peak amplifier and the second peak amplifier can be adjacent to each other.
(7) A Doherty amplifier circuit according to an embodiment of the present disclosure includes a divider that divides a received input signal into a first signal, a second signal, and a third signal, a main amplifier that amplifies the first signal and outputs an amplified first signal as a fourth signal, a first peak amplifier that amplifies the second signal and outputs an amplified second signal as a fifth signal, a second peak amplifier that amplifies the third signal and outputs an amplified third signal as a sixth signal, a combiner that combines the fourth signal, the fifth signal, and the sixth signal into a combined signal and outputs the combined signal to an output terminal as an output signal, a first semiconductor chip including the main amplifier and the first peak amplifier, and a second semiconductor chip different from the first semiconductor chip and including the second peak amplifier. An input power of the input signal at which the second peak amplifier is turned on is larger than an input power of the input signal at which the first peak amplifier is turned on. Thus, the deterioration of the characteristics can be suppressed, and the yield can be improved.
(8) A semiconductor device for a Doherty amplifier circuit according to an embodiment of the present disclosure includes a main amplifier that amplifies a first signal divided from an input signal and outputs an amplified first signal as a fourth signal, a first peak amplifier that amplifies a second signal divided from the input signal and outputs an amplified second signal as a fifth signal, a second peak amplifier that amplifies a third signal divided from the input signal and outputs an amplified third signal as a sixth signal, and a semiconductor chip including the main amplifier, the first peak amplifier, and the second peak amplifier. An input power of the input signal at which the second peak amplifier is turned on is larger than an input power of the input signal at which the first peak amplifier is turned on, and the main amplifier and the first peak amplifier are adjacent to each other. Thus, the deterioration of the characteristics can be suppressed.
(9) A semiconductor device for a Doherty amplifier circuit according to an embodiment of the present disclosure includes a main amplifier that amplifies a first signal divided from an input signal and outputs an amplified first signal as a fourth signal, a first peak amplifier that amplifies a second signal divided from the input signal and outputs an amplified second signal as a fifth signal, a second peak amplifier that amplifies a third signal divided from the input signal and outputs an amplified third signal as a sixth signal, a first semiconductor chip including the main amplifier and the first peak amplifier, and a second semiconductor chip different from the first semiconductor chip and including the second peak amplifier. An input power of the input signal at which the second peak amplifier is turned on is larger than an input power of the input signal at which the first peak amplifier is turned on. Thus, the deterioration of the characteristics can be suppressed, and the yield can be improved.

### Details of Embodiments of Present Disclosure

Specific examples of a Doherty amplifier circuit and a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

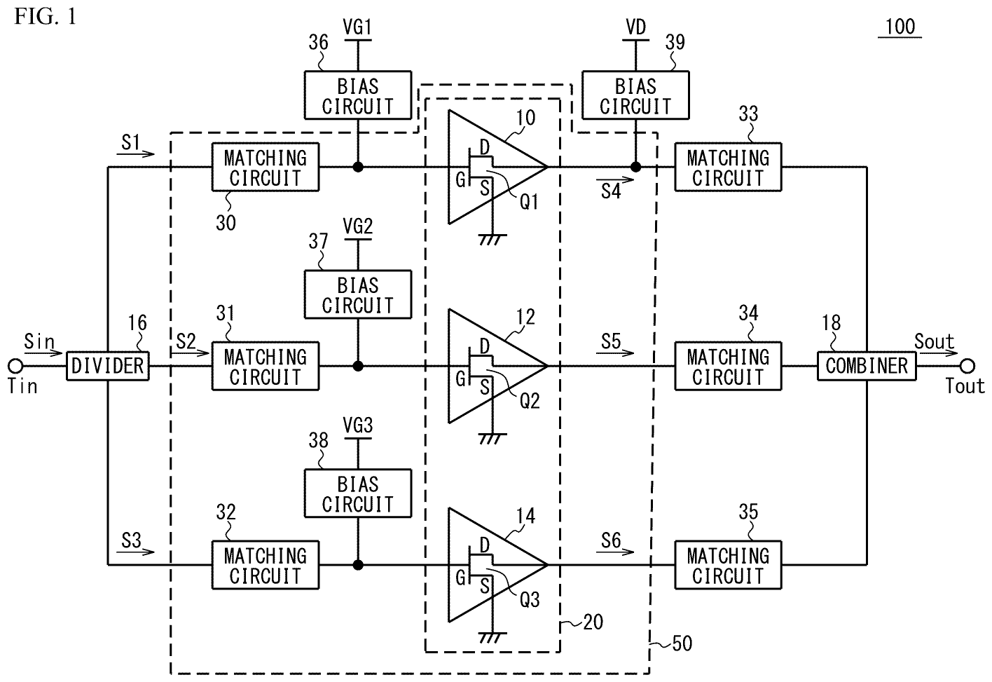

A high-power high-frequency amplifier circuit used in a base station of mobile communication will be described as an example of a Doherty amplifier circuit. In this case, the frequency of the high frequency signal is, for example, 0.5 GHz to 10 GHz. FIG. 1 is a block diagram of a Doherty amplifier circuit according to a first embodiment.

As illustrated in FIG. 1, in a Doherty amplifier circuit 100, a main amplifier 10, a peak amplifier 12 (first peak amplifier), and a peak amplifier 14 (second peak amplifier) are connected in parallel between a divider 16 and a combiner 18. Thus, Doherty amplifier circuit 100 is a 3-way amplifier circuit. The Doherty amplifier circuit may be an N-way Doherty amplifier circuit having three or more peak amplifiers.

A high frequency signal is input to an input terminal Tin as an input signal Sin. Divider 16 divides input signal Sin input to input terminal Tin into signals S1 (first signal), S2 (second signal), and S3 (third signal). Divider 16 is, for example, a Wilkinson-type divider.

A path to which signal S1 is input includes a matching circuit 30, a bias circuit 36, main amplifier 10, a bias circuit 39, and a matching circuit 33. A path to which signal S2 is input includes a matching circuit 31, a bias circuit 37, peak amplifier 12, and a matching circuit 34. A path to which signal S3 is input includes a matching circuit 32, a bias circuit 38, peak amplifier 14, and a matching circuit 35.

Matching circuits 30 to 32 match the impedances seen from divider 16 toward matching circuits 30 to 32 to the impedances seen from matching circuits 30 to 32 toward main amplifier 10 and peak amplifiers 12 and 14, respectively. Bias circuits 36 to 38 supply gate bias voltages VG1 to VG3 to gates G of main amplifier 10 and peak amplifiers 12 and 14, respectively, and suppress the leakage of signals S1 to S3 to the bias terminals.

Main amplifier 10 and peak amplifiers 12 and 14 amplify signals S1, S2 and S3 and output the amplified signals S4 (fourth signal), S5 (fifth signal) and S6 (sixth signal), respectively. Bias circuit 39 supplies a drain bias voltage VD to drains D of main amplifier 10 and peak amplifiers 12 and 14, and suppresses the leakage of signal S4 to the bias terminal. Matching circuits 33 to 35 match the impedances seen from main amplifier 10 and peak amplifiers 12 and 14 toward matching circuits 33 to 35, respectively, to the impedances seen from matching circuits 33 to 35 toward combiner 18. Combiner 18 combines signals S4 to S6 and outputs the combined signal to an output terminal Tout as an output signal Sout.

Main amplifier 10 and peak amplifiers 12 and 14 include transistors Q1 to Q3, respectively. Transistors Q1 to Q3 are, for example, field effect transistors (FETs), such as gallium nitride high electron mobility transistors (GaN HEMTs) or laterally diffused metal oxide semiconductors (LDMOSs). Sources S of transistors Q1 to Q3 are grounded, signals S1 to S3 are input to each of gates G, and signals S4 to S6 are output from each of drains D. Transistors Q1 to Q3 are mounted on a single semiconductor chip 20. Matching circuits 30 to 33 and semiconductor chip 20 are mounted on a package 50.

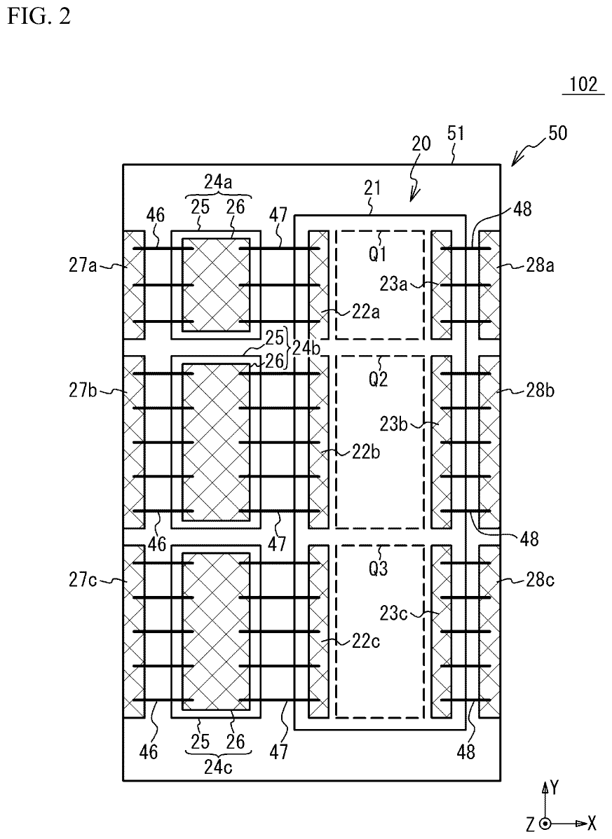

FIG. 2 is a plan view of a semiconductor device in the first embodiment. In FIG. 2, a lid of package 50 is not illustrated. A thickness direction of a base 51 of package 50 is defined as a Z direction, a direction from leads 27a to 27c toward leads 28a to 28c is defined as an X direction (second direction intersecting the first direction), and the direction orthogonal to the X direction and the Z direction is defined as a Y direction (first direction).

As illustrated in FIG. 2, in a semiconductor device 102, package 50 has base 51, at least an upper surface of which is conductive. Base 51 is a conductive substrate, such as a stacked substrate of copper and molybdenum. A reference potential, such as a ground potential, is supplied to base 51. Semiconductor chip 20 and capacitive components 24a to 24c are mounted on base 51.

Leads 27a to 27c are disposed on a side of base 51 in a negative direction of the X direction with insulating layers (not illustrated) interposed between base 51 and leads 27a to 27c. Leads 28a to 28c are disposed on a side of base 51 in a positive direction of the X direction with insulating layers (not illustrated) interposed between base 51 and leads 28a to 28c. Leads 27a to 27c and 28a to 28c are metal layers or metal plates made of, for example, copper. Signals S1 to S3 are input to leads 27a to 27c, respectively, and signals S4 to S6 are output from leads 28a to 28c, respectively.

Semiconductor chip 20 includes a substrate 21, transistors Q1 to Q3, pads 22a to 22c and 23a to 23c disposed on an upper surface of substrate 21, and an electrode (not illustrated) disposed on a lower surface of substrate 21. Pads 22a (first input pad), 23a (first output pad) and the electrode on the lower surface are electrically connected to a gate G (input terminal), a drain D (output terminal) and a source S of transistor Q1, respectively. Pads 22b (second input pad), 23b (second output pad) and the electrode on the lower surface are electrically connected to a gate G (input terminal), a drain D (output terminal) and a source S of transistor Q2, respectively. Pads 22c (third input pad), 23c (third output pad) and the electrode on the lower surface are electrically connected to a gate G (input terminal), a drain D (output terminal) and a source S of transistor Q3, respectively.

Substrate 21 is a semiconductor substrate. When transistors Q1 to Q3 are GaN HEMTs, substrate 21 is, for example, a silicon carbide (SiC) substrate, a sapphire substrate, or a gallium nitride (GaN) substrate. When transistors Q1 to Q3 are LDMOS, substrate 21 is, for example, a silicon (Si) substrate. Pads 22a to 22c, 23a to 23c and the electrodes on the lower surfaces are metal layers, such as gold layers. Although transistor Q1 is illustrated as being smaller than transistors Q2 and Q3 (for example, the gate width is smaller and the saturation power is smaller when the gate bias voltage and the drain bias voltage are the same), transistor Q1 may be the same as transistors Q2 and Q3 (for example, the same gate width and the same saturation power when the gate bias voltage and the drain bias voltage are the same).

Each of capacitive components 24a to 24c include a dielectric substrate 25, an electrode 26 disposed on an upper surface of dielectric substrate 25, and an electrode (not illustrated) disposed on a lower surface of dielectric substrate 25. Electrode 26 and the electrode on the lower surface, which sandwich dielectric substrate 25, form a capacitor. Dielectric substrate 25 is, for example, an alumina substrate or a barium titanate substrate. Electrode 26 is, for example, a metal layer, such as a gold layer.

Bonding wires 46 electrically connect leads 27a to 27c and electrodes 26 of capacitive components 24a to 24c, respectively. Bonding wires 47 electrically connect electrodes 26 of capacitive components 24a to 24c and pads 22a to 22c, respectively. Bonding wires 48 electrically connect pads 23a to 23c and leads 28a to 28c, respectively. Bonding wires 46 to 48 are metal wires, such as gold wires or aluminum wires.

Bonding wires 46 and 47 function as inductors, and capacitive components 24a to 24c function as capacitors. Bonding wires 46 and 47 and capacitive components 24a to 24c correspond to at least a part of matching circuits 30 to 32 of T-type LCL circuits.

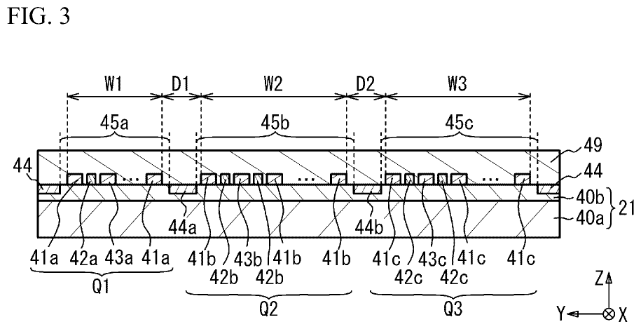

FIG. 3 is a cross-sectional view of a semiconductor chip in the first embodiment. As illustrated in FIG. 3, substrate 21 includes a substrate 40a and a semiconductor layer 40b disposed on substrate 40a. Regions where a part of semiconductor layer 40b is inactivated by ion implantation or the like are inactive regions 44, 44a, and 44b. Regions where semiconductor layer 40b is not inactivated are active regions 45a to 45c. Transistors Q1 to Q3 are disposed on active regions 45a to 45c, respectively. Inactive region 44a is provided between transistors Q1 and Q2, and inactive region 44b is provided between transistors Q2 and Q3.

Transistor Q1 includes a source electrode 41a, a gate electrode 42a, and a drain electrode 43a arranged in the Y direction. Transistor Q2 includes a source electrode 41b, a gate electrode 42b, and a drain electrode 43b arranged in the Y direction. Transistor Q3 includes a source electrode 41c, a gate electrode 42c, and a drain electrode 43c arranged in the Y direction. An insulating layer 49 is disposed on substrate 21 so as to cover transistors Q1 to Q3. Insulating layer 49 is an organic insulating layer, such as a polyimide layer or a benzocycbutene (BCB) layer. At least a part of insulating layer 49 may be an inorganic insulating layer.

When transistors Q1 to Q3 are GaN HEMTs, substrate 40a is, for example, a silicon carbide substrate, and semiconductor layer 40b includes a gallium nitride transit layer and an aluminum gallium nitride barrier layer. Source electrodes 41a to 41c and drain electrodes 43a to 43c are metal films, and are, for example, titanium films and aluminum films stacked in this order from semiconductor layer 40b. Gate electrodes 42a to 42c are metal films, and are, for example, nickel films and gold films stacked in this order from semiconductor layer 40b

In transistors Q1 to Q3, the thicknesses of the respective layers of semiconductor layer 40b are substantially the same. For example, in transistors Q1 to Q3, the thicknesses of the gallium nitride transit layers are the same as each other, and the thicknesses of the aluminum gallium nitride barrier layers are the same as each other. In addition, in transistors Q1 to Q3, the sizes of source electrodes 41a to 41c are the same as each other, the sizes of gate electrodes 42a to 42c are the same as each other, and the sizes of drain electrodes 43a to 43c are the same as each other.

Thus, the characteristics per unit gate widths of transistors Q1 to Q3 are substantially the same as each other e. For example, in transistors Q1 to Q3, the gate source capacitances per unit gate widths are substantially the same as each other, the drain source capacitances per unit gate widths are substantially the same as each other, and the gate drain capacitances per unit gate widths are substantially the same as each other.

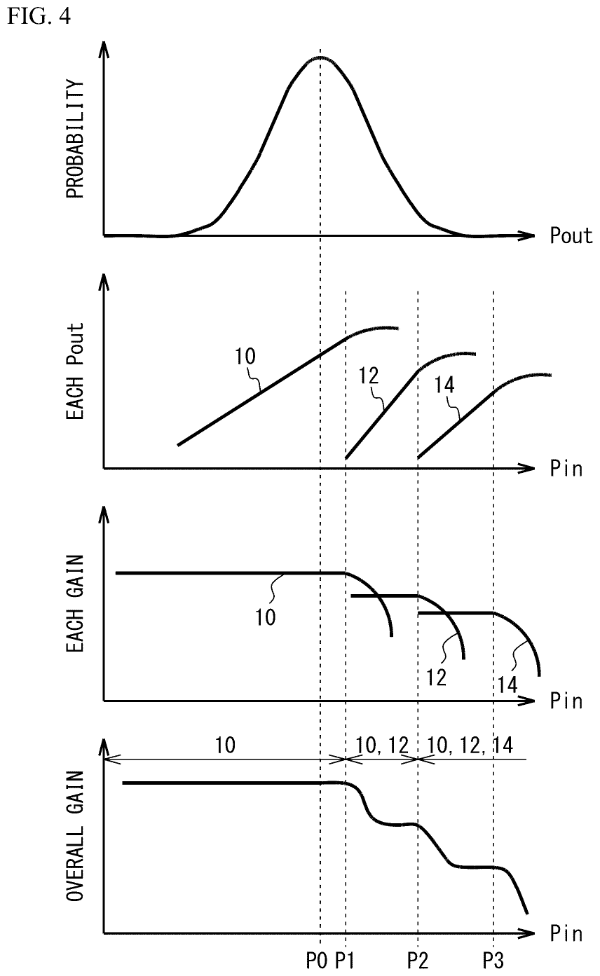

FIG. 4 is a schematic diagram illustrating the probability for Pout, Pout of each amplifier for Pin, the gain of each amplifier for Pin, and the overall gain for Pin in the first embodiment.

The probability is a probability of a modulated wave signal of a high frequency signal for mobile communication amplified by Doherty amplifier circuit 100. That is, the probability is a probability that Doherty amplifier circuit 100 outputs a certain output power Pout. Each Pout is output power Pout of each of main amplifier 10 and peak amplifiers 12 and 14. Each gain is a power gain of each of main amplifier 10 and peak amplifiers 12 and 14. The overall gain is a power gain of output power Pout of output signal Sout with respect to an input power Pin of input signal Sin. Pin and Pout are expressed in dB. The gain of main amplifier 10 at a power P1 or less of each gain is larger than the gain of peak amplifier 12 at power P1 or more and a power P2 or less. That is, the slope of Pout with respect to input power Pin at a power equal to or less than power P1 in main amplifier 10 is larger than the slope of Pout with respect to input power Pin at power P1 or more and power P2 or less in peak amplifier 12. However, FIG. 4 is a schematic diagram, and the slope of Pout with respect to input power Pin at a power equal to or less than power P1 for main amplifier 10 is illustrated to be smaller than the slope of Pout with respect to input power Pin at power P1 or more and power P2 or less for peak amplifier 12.

As illustrated in FIG. 4, when output power Pout is a power P0, the probability of the modulated wave is the highest. That is, when the signal of the modulated wave is output, the time during which output power Pout is power P0 is the longest. Main amplifier 10 is a class-A or class-AB amplifier, and peak amplifiers 12 and 14 are class-C amplifiers. Input power Pin at which peak amplifier 12 is turned on is larger than input power Pin at which main amplifier 10 is turned on, and input power Pin at which peak amplifier 14 is turned on is larger than input power Pin at which peak amplifier 12 is turned on. This operation can be achieved by making a gate bias voltage VG2 of transistor Q2 negatively larger than a gate bias voltage VG1 of transistor Q1 and making a gate bias voltage VG3 of transistor Q3 negatively larger than gate bias voltage VG2 of transistor Q2.

When input power Pin of input signal Sin increases, at input power Pin more than power P0 and power P1 or less, main amplifier 10 operates, but peak amplifiers 12 and 14 do not operate. When input power Pin is equal to or less than power P1, output power Pout of main amplifier 10 increases linearly as input power Pin increases. Thus, when input power Pin is equal to or less than power P0, each gain and the overall gain are substantially constant.

When input power Pin is equal to or more than power P1 and equal to or less than power P2, main amplifier 10 and peak amplifier 12 operate, but peak amplifier 14 does not operate. In this range, main amplifier 10 is saturated. Thus, the gain of main amplifier 10 is reduced. The overall gain is also reduced along with reducing the gain of main amplifier 10. Since peak amplifier 12 is performed in class-C operation, the gain of peak amplifier 12 between power P1 and power P2 is lower than the gain of main amplifier 10 at a power equal to or less than power P1. Also, the saturation power of peak amplifier 12 is smaller than the saturation power of main amplifier 10.

When input power Pin is equal to or more than power P2 and equal to or less than a power P3, all of main amplifier 10 and peak amplifiers 12 and 14 operate. In this range, peak amplifier 12 is saturated in addition to main amplifier 10. Thus, the gain of peak amplifier 12 is reduced. The overall gain also is reduced along with reducing the gain of main amplifier 12. Since the operating point of peak amplifier 14 is negatively larger than the operating point of peak amplifier 12, the gain of peak amplifier 14 between powers P2 and P3 is lower than the gain of peak amplifier 12 between powers P1 and P2. Also, the saturation power of peak amplifier 14 is smaller than the saturation power of peak amplifier 12.

When input power Pin is equal to or more than power P3, peak amplifier 14 is saturated in addition to main amplifier 10 and peak amplifier 12. Thus, the gain of peak amplifier 14 is reduced. The overall gain is also reduced along with reducing the gain of main amplifier 14.

The product of the probability and the overall gain corresponds to the gain of the modulated wave. In order to improve the gain of the modulated wave, the overall gain at Pout having a high probability is improved.

### Comparative Example

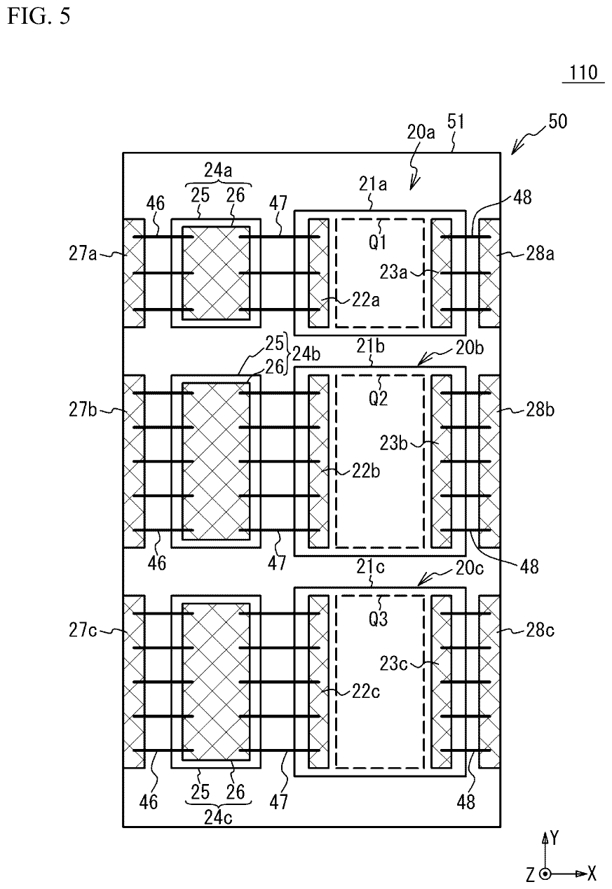

FIG. 5 is a plan view of a semiconductor device in a comparative example. As illustrated in FIG. 5, in a semiconductor device 110 of the comparative example, transistors Q1 to Q3 are mounted on different semiconductor chips 20a to 20c, respectively. Semiconductor chips 20a to 20c include substrates 21a to 21c, respectively. When semiconductor chips 20a to 20c are different from each other, parasitic capacitance (for example, gate source capacitance, drain source capacitance, and gate drain capacitance) between transistors Q1 to Q3 varies due to manufacturing variation or the like. For example, when semiconductor chips 20a to 20c are obtained from different wafers, the parasitic capacitances of transistors Q1 to Q3 are likely to be different from each other. Even when semiconductor chips 20a to 20c are obtained from the same wafer, if the positions of semiconductor chips 20a to 20c in the wafer are different from each other, the parasitic capacitances of transistors Q1 to Q3 are likely to be different from each other. Thus, it is difficult to match the phases of main amplifier 10 and peak amplifiers 12 and 14. When the phases of signals S4 to S6 are shifted from a desired relationship, the gain of output signal Sout is reduced.

### Description of First Embodiment

According to the first embodiment, as illustrated in FIG. 2, main amplifier 10 and peak amplifiers 12 and 14 are mounted on the identical semiconductor chip 20. The difference in parasitic capacitance or the like between transistors Q1 and Q3 disposed in adjacent regions in semiconductor chip 20 is small. Thus, the phases of signals S4 to S6 output from main amplifier 10 and peak amplifiers 12 and 14 can be matched. Thus, it is possible to suppress the deterioration of the characteristics, such as the gain of output signal Sout.

As illustrated in FIG. 4, when input power Pin at which main amplifier 10 and peak amplifier 12 is operated is between power P1 and power P2, the probability of the modulated wave is high. Thus, the gain of the modulated wave can be improved by setting the phases of main amplifier 10 and peak amplifier 12 within a desired range. Thus, as illustrated in FIG. 2, main amplifier 10 and peak amplifier 12 are adjacent to each other in the Y direction. Since transistors Q1 and Q2 are adjacent to each other, the difference in parasitic capacitance or the like between transistors Q1 and Q2 is reduced. Thus, the phase difference between main amplifier 10 and peak amplifier 12 can be reduced. Thus, the deterioration of the characteristics, such as the gain of the modulated wave, can be suppressed. Main amplifier 10 and peak amplifier 12 being adjacent to each other means that no other transistor, no passive element, or no wiring is provided between main amplifier 10 and peak amplifier 12.

As illustrated in FIG. 4, when input power Pin at which main amplifier 10 and peak amplifiers 12 and 14 is operated is equal to or more than power P2, the probability of the modulated wave is low. Thus, peak amplifier 14 does not affect the gain of the modulated wave as much as peak amplifier 12. Thus, peak amplifier 12 may be disposed between main amplifier 10 and peak amplifier 14.

As illustrated in FIG. 3, the widths of main amplifier 10 and peak amplifiers 12 and 14 (i.e., transistors Q1 to Q3) in the Y direction are denoted by W1, W2 and W3, respectively. A distance between main amplifier 10 and peak amplifier 12 is denoted by D1, and a distance between peak amplifiers 12 and 14 is denoted by D2. When a distance D1 reduces, the difference in parasitic capacitance between transistors Q1 and Q2 reduces. Thus, the deterioration of the characteristics can be suppressed. From this viewpoint, distance D1 can be set to be equal to or less than a width W1 and equal to or less than a width W2, can be set to be equal to or less than 0.5 times widths W1 and W2, or can be set to be equal to or less than 0.2 times widths W1 and W2. From the viewpoint of reducing the variation in parasitic capacitance between transistors Q2 and Q3, a distance D2 can be set to be equal to or less than widths W2 and W3, can be set to be equal to or less than 0.5 times widths W2 and W3, or can be set to be equal to or less than 0.2 times widths W2 and W3.

As illustrated in FIG. 2, pads 22a and 23a electrically connected to the input terminal and the output terminal of main amplifier 10, respectively, are disposed on semiconductor chip 20. Pads 22b and 23b electrically connected to the input terminal and the output terminal of peak amplifier 12, respectively, are disposed on semiconductor chip 20. Pads 22c and 23c electrically connected to the input terminal and the output terminal of peak amplifier 14, respectively, are disposed on semiconductor chip 20. Main amplifier 10 and peak amplifiers 12 and 14 can be electrically connected to external circuits, such as matching circuits 30 to 35.

Main amplifier 10 and peak amplifiers 12 and 14 are arranged in the Y direction. Pads 22a and 23a are located with main amplifier 10 interposed therebetween in the X direction. Pads 22b and 23b are located with peak amplifier 12 interposed therebetween in the X direction. Pads 22c and 23c are located with peak amplifier 14 interposed therebetween in the X direction. Thus, pads 22a to 22c and 23a to 23c are not disposed between main amplifier 10 and peak amplifier 12 or between peak amplifiers 12 and 14. Thus, main amplifier 10 and peak amplifier 12 can be adjacent to each other, and peak amplifiers 12 and 14 can be adjacent to each other.

No passive element such as an inductor or a capacitor is disposed on semiconductor chip 20. Thus, no passive element is disposed between main amplifier 10 and peak amplifier 12 and between peak amplifiers 12 and 14. Thus, main amplifier 10 and peak amplifier 12 can be adjacent to each other, and peak amplifiers 12 and 14 can be adjacent to each other.

### Second Embodiment

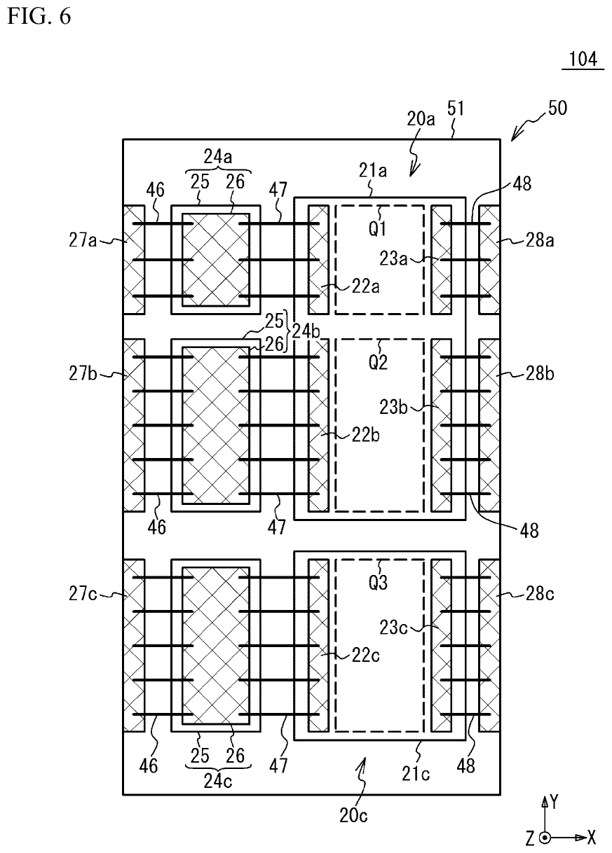

FIG. 6 is a plan view of a semiconductor device in a second embodiment. As illustrated in FIG. 6, in a semiconductor device 104 of the second embodiment, transistors Q1 and Q2 are mounted on semiconductor chip 20a, and transistor Q3 is mounted on semiconductor chip 20c. Semiconductor chips 20a and 20c include substrates 21a and 21c, respectively. Transistors Q1 and Q2 are disposed adjacent to each other on substrate 21a. The other configurations are the same as those of the first embodiment, and the description thereof is omitted.

In order to improve the gain of the modulated wave, it is effective to reduce the phase difference between main amplifier 10 and peak amplifier 12. Thus, semiconductor chip 20a (first semiconductor chip) includes main amplifier 10 and peak amplifier 12. Thus, the phase difference between main amplifier 10 and peak amplifier 12 is reduced, and the gain of the modulated wave can be improved. On the other hand, when three amplifiers are disposed on the identical semiconductor chip 20 as in the first embodiment, semiconductor chip 20 is determined to be non-defective when all the three amplifiers are non-defective. Thus, the yield of semiconductor chip 20 is reduced. Thus, peak amplifier 14 that does not affect the gain of the modulated wave as much as peak amplifier 12 is mounted on semiconductor chip 20c (second semiconductor chip) different from semiconductor chip 20a. Thus, the yield of semiconductor chips 20a and 20c can be improved.

Main amplifier 10 and peak amplifier 12 are adjacent to each other on semiconductor chip 20a. Thus, the difference in parasitic capacitance between transistors Q1 and Q2 is reduced. Thus, the deterioration of the characteristics can be suppressed. Referring to FIG. 3, also in a first modification of the first embodiment, distance D1 between main amplifier 10 and peak amplifier 12 in the Y direction can be set to be equal to or less than width W1 of main amplifier 10 in the Y direction and equal to or less than width W2 of peak amplifier 12 in the Y direction, can be set to be equal to or less than 0.5 times widths W1 and W2, or can be set to be equal to or less than 0.2 times widths W1 and W2.

Although the first embodiment and its modification have been described by taking a 3-way Doherty amplifier circuit as an example, in the case of an N-way Doherty amplifier circuit, N-1 peak amplifiers may be provided.

The embodiments disclosed here should be considered illustrative in all respects and not restrictive. The present disclosure is not limited to the specific embodiments described above, but various variations and changes are possible within the scope of the gist of the present disclosure as described in the claims.

1. A Doherty amplifier circuit comprising:
a divider that divides a received input signal into a first signal, a second signal, and a third signal;
a main amplifier that amplifies the first signal and outputs an amplified first signal as a fourth signal;
a first peak amplifier that amplifies the second signal and outputs an amplified second signal as a fifth signal;
a second peak amplifier that amplifies the third signal and outputs an amplified third signal as a sixth signal;
a combiner that combines the fourth signal, the fifth signal, and the sixth signal into a combined signal and outputs the combined signal to an output terminal as an output signal; and
a semiconductor chip including the main amplifier, the first peak amplifier, and the second peak amplifier, wherein
an input power of the input signal at which the second peak amplifier is turned on is larger than an input power of the input signal at which the first peak amplifier is turned on, and
the main amplifier and the first peak amplifier are adjacent to each other.

2. The Doherty amplifier circuit according to claim 1, wherein
the first peak amplifier is disposed between the main amplifier and the second peak amplifier.

3. The Doherty amplifier circuit according to claim 1, wherein
the main amplifier and the first peak amplifier are adjacent to each other in a first direction, and
a distance between the main amplifier and the first peak amplifier is smaller than a width of the main amplifier in the first direction and smaller than a width of the first peak amplifier in the first direction.

4. The Doherty amplifier circuit according to claim 1, further comprising:
a first input pad disposed on the semiconductor chip and electrically connected to an input terminal of the main amplifier;
a second input pad disposed on the semiconductor chip and electrically connected to an input terminal of the first peak amplifier;
a third input pad disposed on the semiconductor chip and electrically connected to an input terminal of the second peak amplifier;
a first output pad disposed on the semiconductor chip and electrically connected to an output terminal of the main amplifier;
a second output pad disposed on the semiconductor chip and electrically connected to an output terminal of the first peak amplifier; and
a third output pad disposed on the semiconductor chip and electrically connected to an output terminal of the second peak amplifier.

5. The Doherty amplifier circuit according to claim 4, wherein
the main amplifier, the first peak amplifier, and the second peak amplifier are arranged in a first direction,
the first input pad and the first output pad are located with the main amplifier interposed therebetween in a second direction intersecting the first direction,
the second input pad and the second output pad are located with the first peak amplifier interposed therebetween in the second direction, and
the third input pad and the third output pad are located with the second peak amplifier interposed therebetween in the second direction.

6. The Doherty amplifier circuit according to claim 1, wherein
the semiconductor chip includes no passive element.

7. A Doherty amplifier circuit comprising:
a divider that divides a received input signal into a first signal, a second signal, and a third signal;
a main amplifier that amplifies the first signal and outputs an amplified first signal as a fourth signal;
a first peak amplifier that amplifies the second signal and outputs an amplified second signal as a fifth signal;
a second peak amplifier that amplifies the third signal and outputs an amplified third signal as a sixth signal;
a combiner that combines the fourth signal, the fifth signal, and the sixth signal into a combined signal and output the combined signal to an output terminal as an output signal;
a first semiconductor chip including the main amplifier and the first peak amplifier; and
a second semiconductor chip different from the first semiconductor chip and including the second peak amplifier, wherein
an input power of the input signal at which the second peak amplifier is turned on is larger than an input power of the input signal at which the first peak amplifier is turned on.

8. A semiconductor device for a Doherty amplifier circuit, the semiconductor device comprising:
a main amplifier that amplifies a first signal divided from an input signal and outputs an amplified first signal as a fourth signal;
a first peak amplifier that amplifies a second signal divided from the input signal and outputs an amplified second signal as a fifth signal;
a second peak amplifier that amplifies a third signal divided from the input signal and outputs an amplified third signal as a sixth signal; and
a semiconductor chip including the main amplifier, the first peak amplifier, and the second peak amplifier, wherein
an input power of the input signal at which the second peak amplifier is turned on is larger than an input power of the input signal at which the first peak amplifier is turned on, and
the main amplifier and the first peak amplifier are adjacent to each other.
